(19) United States
(12) Patent Application Publication
(10) Pub. No.: US 2007/0074661 A1
(43) Pub. Date: Apr. 5, 2007

(54) CVD reactor with stabilized process chamber height

(75) Inventors: Walter Franken, Eschweiler (DE); Johannes Kappeler, Wurselen (DE)

Correspondence Address: ST. ONGE STEWARD JOHNSTON & REENS, LLC, 986 BEDFORD STREET, STAMFORD, CT, 06905-5619, US

(73) Assignee: AIXTRON AG

(21) Appl. No.: 11/511,110

(22) Filed: Aug. 28, 2006

Related U.S. Application Data
(63) Continuation of application No. PCT/EP05/50242, filed on Jan. 20, 2005.

(30) Foreign Application Priority Data
Feb. 28, 2004 (DE) 102004009772.0

(51) Int. Cl. C23C 16/00

(52) U.S. Cl. 118/715

(57) ABSTRACT

The invention relates to a CVD reactor which comprises a process chamber, disposed inside a reactor housing and having process chamber walls, a process chamber bottom and a process chamber ceiling spaced apart by a distance from the process chamber bottom. The reactor housing comprises at least one reactor wall which can be slightly elastically deformed when the pressure within the reactor housing changes. Said reactor wall is provided with an especially center opening through which a functional element projects. Said functional element is firmly linked via a first section with a process chamber wall and has a second section that is located outside the reactor housing. In order to increase the reproducibility of results, the functional element is linked with the reactor wall so as to elastically yield.

### CROSS-REFERENCE TO RELATED APPLICATIONS

The present application is a continuation of pending International patent application PCT/EP2005/050242 filed on Jan. 20, 2005 which designates the United States and claims priority from German patent application 10 2004 009 772.0 filed on Feb. 28, 2004, the content of which is incorporated herein by reference.

### FIELD OF THE INVENTION

The invention relates to a CVD reactor with a process chamber disposed in a reactor housing, which chamber, comprising process chamber walls, has a process chamber floor and a process chamber ceiling, spaced at a distance from the process chamber floor, the reactor housing having at least one reactor wall which can be elastically deformed slightly when the pressure within the reactor housing changes, which reactor wall has, in particular at the center, an opening through which there projects a functional element, which is fixedly connected by a first portion to a process chamber wall and has a second portion, which is disposed outside the reactor housing.

### BACKGROUND OF THE INVENTION

CVD reactors of this type are known from DE 10043597 A1, DE 10043599 A1, DE 10043600 A1, DE 10043601 A1, DE 10057134 A1, DE 10064941 A1, DE 10064942 A1, DE 10064944 A1, DE 10124609 A1, DE 10133914A1, DE 10136858A1, DE 10153463A1 and DE 10211442A1.

The known CVD reactors have a reactor housing in which a process chamber is disposed. The reactor housing has an upper wall and a lower wall and also a lateral wall, surrounding the process chamber. At the center of the upper wall, and possibly at the center of the lower wall, there are openings. Through the opening in the upper wall, which is also referred to as the reactor ceiling, a gas inlet member projects from the outside into the reactor housing. The process gases are introduced into the process chamber through this gas inlet member. The gas inlet member is usually at the center of the reactor and is at the same time a support for a process chamber ceiling providing the upper delimitation of the process chamber. The process chamber floor, lying opposite the process chamber ceiling, may be connected either to the floor of the reactor housing, to the reactor housing wall or to a rotary drive projecting through the opening in the floor. The height of the process chamber is the clear distance between the process chamber ceiling and the process chamber floor. This dimension is critical for certain processes taking place inside the process chamber. It must remain constant.

The processes occurring in the process chamber take place under different total pressures, which are generally lower than atmospheric pressure. The total pressures inside the process chamber may consequently vary in a range between zero and 1000 mbar. These pressure variations are accompanied by deformation of the reactor ceiling and reactor floor, serving as pressure barriers. In the case of the known CVD reactors, at least the process chamber ceiling is rigidly connected to the gas inlet member, which is fixedly connected to the center of the process chamber ceiling. The reactor ceiling can in this case be removed from the reactor. At the same time, the process chambers are also opened for loading and unloading. This design has the consequence that the distance between the process chamber ceiling and the process chamber floor may change, depending on the total pressure inside the process chamber. In order to counteract this effect, it has been the practice to stiffen the process chamber ceiling or the process chamber floor.

To increase productivity, larger process chambers are required. This leads to larger diameters of the process chamber walls and consequently to an increase in the deformation accompanying a change in total pressure.

An object of the invention is to provide measures for keeping the height of the process chamber constant.

### SUMMARY OF THE INVENTION

The object is achieved by the invention specified in the claims.

Claim 1 provides first and foremost that the functional element is connected to the reactor wall in such a way that it can elastically yield. The process chamber floor can then be rigidly connected to the process chamber ceiling by suitable means. This rigid connection takes place without involving the two opposing reactor walls. This has the consequence that both the reactor floor and the reactor ceiling can be made less stiff. Their deformation no longer has an effect on the distance between the process chamber floor and the process chamber ceiling. Rather, the distance is defined by the elements which connect the process chamber ceiling to the process chamber floor. The elastically yielding connection between functional element and reactor wall takes place in particular by the functional element, that is to say the gas inlet member or a drive shaft projecting through the reactor floor, passing through an opening in the reactor ceiling or the reactor floor. The gas inlet member is then fixedly connected to the process chamber ceiling and the drive shaft is fixedly connected to the process chamber floor. The process chamber floor may at the same time form a substrate holder. The drive shaft may be rotatably mounted on a supporting structure which is disposed in the reactor housing and is rigidly connected to a side wall of the reactor housing or to the edge of a wall. However, it is also possible for the supporting structure which provides a rotatable mounting for the drive shaft to be disposed outside the reactor housing. It can then be used for rigidly connecting the drive shaft to the gas inlet member. The process chamber ceiling may, however, also be rigidly connected to a side wall or to the edge of the reactor ceiling, since the edge of the reactor ceiling deforms only slightly when there is a change in pressure. This is advantageous if the reactor ceiling forms a cover which can be opened for loading and unloading. The process chamber floor may have supplementary units, such as a gas discharge ring, a process chamber heater or substrate carrier. The latter may be rotatably disposed on the process chamber floor. The opening at which the functional element projects through the reactor wall is preferably sealed by means of a bellows. This bellows is an elastic connecting element between the functional element and the wall associated with the functional element and preferably consists of high-grade steel. Furthermore, it may be provided that an assembly comprising the process chamber floor, a gas discharge ring, a process chamber heater and a drive shaft is fixedly connected to a rigid supporting structure disposed in the reactor housing, it being possible for the reactor wall to move/deform with respect to the supporting structure when there is deformation within the reactor housing. In a variant of the invention, it is provided that the process chamber ceiling and the process chamber floor are rigidly connected to each other in particular by connecting means at the edge. In this configuration, the entire process chamber can consequently be suspended from the gas inlet member. The connecting elements which rigidly connect the process chamber floor to the process chamber ceiling may be disposed both inside and outside the reactor. These connecting elements may even be formed by elements of the wall of the reactor which do not deform in the direction in which they provide a rigid connection. For instance, the side wall surrounding the process chamber can perform this function in particular. It is sufficient if the process chamber ceiling is merely supported there.

### BRIEF DESCRIPTION OF THE DRAWINGS

Exemplary embodiments of the invention are explained below with reference to the accompanying drawing, in which:

FIG. 1 shows a first exemplary embodiment of the invention in half-section,

FIG. 2 shows a second exemplary embodiment of the invention in half-section,

FIG. 3 shows a third exemplary embodiment of the invention in half-section and

FIG. 4 shows a fourth exemplary embodiment of the invention in half-section.

### DETAILED DESCRIPTION OF THE INVENTION

The reactor housing represented in the exemplary embodiments has in each case a reactor ceiling 3, substantially in the form of a circular disk, which lies opposite a reactor floor 4, which is likewise substantially of a circular form. However, the cross-sectional shape of the reactor may also deviate from that of a round form. The reactor chamber disposed between the reactor floor 4 and the reactor ceiling 3 is laterally surrounded by a tubular reactor side wall 5.

The reactor ceiling 3 has a central opening 17, through which a gas inlet member 9 projects into the interior of the reactor housing 1. The gas inlet member 9 has a portion 9″ lying outside the reactor housing 1 and a portion 9′ disposed inside the reactor housing 1. Process gases are introduced into the process chamber 2 through the gas inlet member, as described in particular in the documents cited at the beginning. The process gases are discharged again through a gas discharge 21.

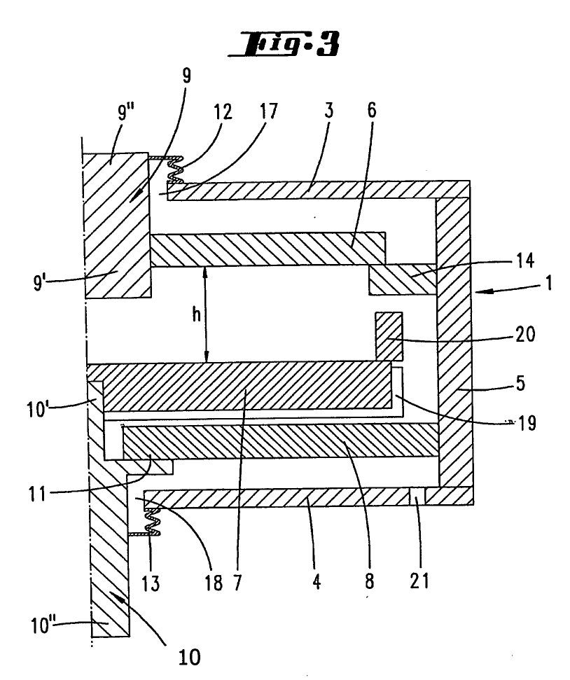

The process chamber 2 is delimited in the upward direction by a process chamber ceiling 6 and in the downward direction by a process chamber floor 7 running parallel to the process chamber ceiling 6. The process chamber floor 7, which is at a distance h from the process chamber ceiling 6, forms the substrate holder or susceptor. On the process chamber floor 7, the substrates to be coated are disposed in an annular arrangement around the gas inlet member 9 at the center. The process gas flowing out from the gas inlet member 9 flows through the circular disk-shaped process chamber 2 from the center to the periphery. The periphery may have gas discharge means (not represented), in particular a gas discharge ring. FIG. 3 schematically shows such a gas discharge ring 20.

A heater 19 for the process chamber floor 7 is likewise only schematically represented. The process chamber ceiling 6 may also be heated. Both the heater 19 and the gas discharge ring 20 may form an assembly together with the process chamber floor 7.

The opening 17 in the reactor ceiling 3, through which the gas inlet member projects, is closed by a bellows 12 of high-grade steel, so that elastic deformation of the reactor ceiling 3 is possible without the position of the gas inlet member 9 or of the process chamber ceiling 6 that is fixedly connected to the gas inlet member 9 changing with respect to the process chamber floor 7.

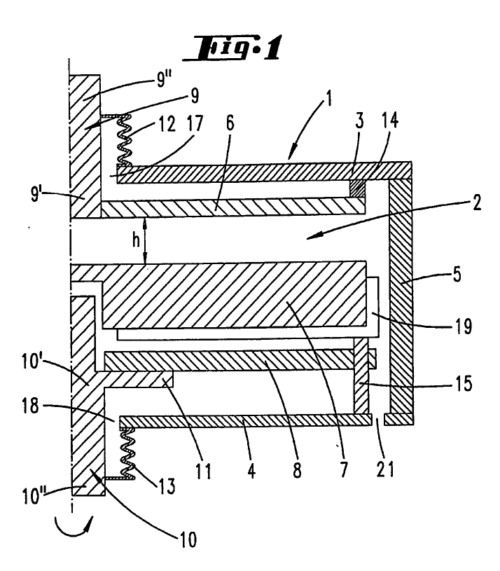

In the case of the exemplary embodiment represented in FIG. 1, the reactor floor 4 likewise has a substantially central opening 18. Through this central opening 18 there projects a drive shaft 10, which is rotationally driven by drive members (not represented) disposed outside the reactor housing 1. Inside the reactor housing 1 is a rotary bearing 11, at which the drive shaft 10 is fixedly connected to a supporting structure 8, which is rigidly connected to the reactor side wall 5 by means of a connecting element 15. The connecting element 15 is located at the edge of the reactor floor 4.

At the outer edge of the reactor ceiling 3 there is a connecting element 14, by which the process chamber ceiling 6 is rigidly connected to the edge of the reactor ceiling 3. The edges of the reactor ceiling 3 and the reactor floor 4 are rigidly connected to each other by means of the reactor side wall 5. As a result of this mechanical construction, the rotary bearing 11 is rigidly connected to the gas inlet member. The process chamber can be opened by lifting off the reactor ceiling 3.

The portion 10′ of the drive shaft 10 projecting into the reactor housing 1 is fixedly connected to the process chamber floor 7, so that the drive shaft 10 can rotationally drive the process chamber floor 7.

The heater, designated by the reference numeral 19 and only schematically represented, may be rigidly connected directly to the supporting structure 8.

The opening 18 passed through by the drive shaft 10 is sealed by a bellows 13.

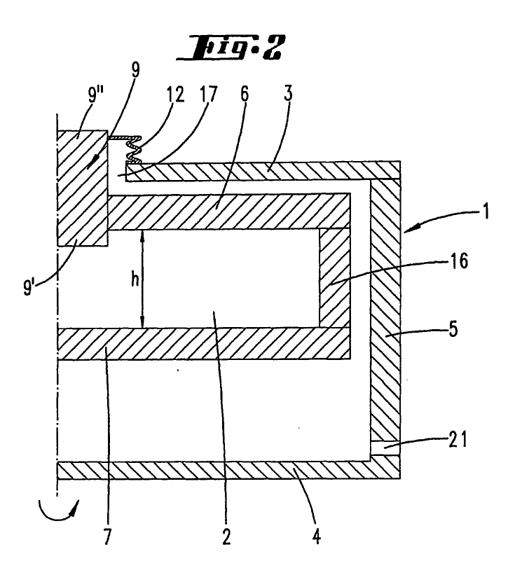

In the case of the CVD reactor represented in FIG. 2, the process chamber ceiling 6 is rigidly connected to the gas inlet member 9. However, there the process chamber ceiling 6 is connected to the process chamber floor 7 directly by means of a process chamber side wall 16. The process chamber side wall 16 may form a gas discharge ring.

In the case of the exemplary embodiment represented in FIG. 3, the process chamber ceiling 6 is rigidly connected to the hollow-cylindrical reactor side wall 5 by means of a connecting element 14. It is merely supported there, so that here, too, the process chamber can be opened by removing the reactor ceiling 3. The supporting structure 8, which supports the drive shaft 10 by means of a rotary bearing 11, is in the case of this exemplary embodiment also connected to the reactor side wall 5.

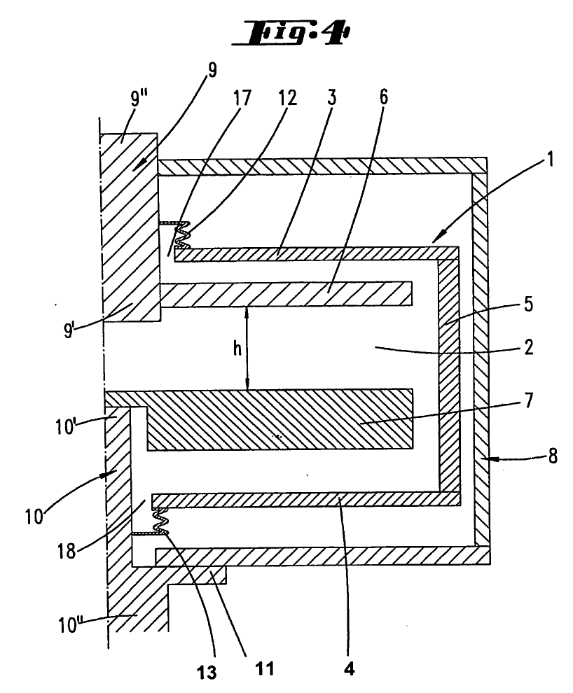

In the case of the exemplary embodiment represented in FIG. 4, the rotary bearing 11 of the drive shaft 10 is disposed outside the reactor housing 1. It is disposed on a supporting structure 8 which reaches around the outside of the reactor housing 1 and on which the gas inlet member 9 is also located. In the case of this exemplary embodiment, gas inlet member 9 and drive shaft 10 are rigidly connected to the supporting structure 8.

All disclosed features are (in themselves) pertinent to the invention. The disclosure content of the associated/accompanying priority documents (copy of the prior application) is also hereby incorporated in full in the disclosure of the application, including for the purpose of incorporating features of these documents in claims of the present application. The documents cited in this application are also expressly incorporated in the disclosure content of this application.

1. CVD reactor with a process chamber disposed in a reactor housing, for carrying out processes at pressures of between 0 and 1000 mbar, which chamber, comprising process chamber walls, has a process chamber floor and a process chamber ceiling, spaced at a distance from the process chamber floor, the reactor housing having at least one reactor wall which can be elastically deformed slightly when the pressure within the reactor housing changes, which reactor wall has, in particular at the center, an opening through which there projects a functional element, which is fixedly connected by a first portion to a process chamber wall and has a second portion, which is disposed outside the reactor housing, characterized in that the functional element is connected to the reactor wall in such a way that it can elastically yield and the functional element is either a gas inlet member rigidly connected to the process chamber ceiling or a drive shaft for the process chamber floor, which forms a substrate holder, so that the process chamber floor is rigidly connected to the process chamber ceiling without involving the two opposing reactor walls.

2. CVD reactor according to claim 1, characterized in that the process chamber floor is rigidly connected to the process chamber ceiling, in particular at its edge.

3. CVD reactor according to claim 1, characterized in that the gas inlet member projects through an opening in the reactor ceiling, the latter in particular of a circular form.

4. CVD reactor according to claim 1, characterized in that the drive shaft projects through an opening in the reactor floor, the latter in particular of a circular form.

5. CVD reactor according to claim 1, characterized in that the drive shaft is rotatably mounted on a supporting structure disposed in the reactor housing and rigidly connected to a side wall of the reactor housing or to the edge of a wall.

6. CVD reactor according to claim 1, characterized in that the process chamber ceiling is rigidly connected to a side wall or to the edge of a reactor ceiling.

7. CVD reactor according to claim 1, characterized by further units rigidly connected to the process chamber floor, such as a gas discharge ring, a process chamber heater or additional substrate carriers.

8. CDV reactor according to claim 1, characterized in that the functional element is connected to the associated wall by means of a bellows.

9. CVD reactor according to claim 1, characterized in that an assembly comprising the process chamber floor, a gas discharge ring, a process chamber floor heater and a drive shaft is fixedly connected to a supporting structure rigidly disposed in the reactor housing, it being possible for the reactor wall to move/deform with respect to the supporting structure when there is variation in pressure within the reactor housing.

10. CVD reactor according to claim 1, characterized in that the process chamber ceiling and the process chamber floor are rigidly connected to each other by means of a process chamber side wall, formed in particular as a gas discharge ring.

11. CVD reactor according to claim 1, characterized in that the gas inlet member and the drive shaft are rigidly connected to each other by means of a supporting structure disposed outside the reactor housing.
